(19) United States
(12) Patent Application Publication
(10) Pub. No.: US 2024/0400860 A1
(43) Pub. Date: Dec. 5, 2024

(54) POLISHING COMPOSITION AND METHOD FOR CONDUCTING A MATERIAL REMOVING OPERATION

(71) Applicant: SAINT-GOBAIN CERAMICS & PLASTICS, INC., Worcester, MA (US)

(72) Inventors: Renjie ZHOU, Alhambra, CA (US); Lin Fu, Rancho Palos Verdes, CA (US); Long Huy Bui, Orange, CA (US); Chun-Lung Kuan, Anaheim, CA (US)

(21) Appl. No.: 18/680,497

(22) Filed: May 31, 2024

Related U.S. Application Data
(60) Provisional application No. 63/505,605, filed on Jun. 1, 2023.

(51) Int. Cl. C09G 1/02

(52) U.S. Cl. CPC C09G 1/02

(57) ABSTRACT

A polishing composition can comprise: an aluminum (III) salt, a permanganate salt, and water, wherein an amount of the permanganate salt can be at least 2.5 wt % based on a total weight of the polishing composition; an amount of the aluminum (II) salt can be at least 0.2 wt % based on the total weight of the polishing composition; and the pH of the composition is not greater than 4.5.

### CROSS-REFERENCE TO RELATED APPLICATION(S)

This application claims priority under 35 U.S.C. § 119 (c) to U.S. Patent Application No. 63/505,605, entitled “POLISHING COMPOSITION AND METHOD FOR CONDUCTING A MATERIAL REMOVING OPERATION,” by Renjie ZHOU et al., filed Jun. 1, 2023, which is assigned to the current assignee hereof and incorporated herein by reference in its entirety.

### FIELD OF THE DISCLOSURE

The present disclosure relates to a polishing composition for conducting a material removal operation, specifically a polishing composition including an aluminum (III)-salt and a permanganate salt, and a method of conducting the material removing operation.

### BACKGROUND

Polishing compositions which assist a polishing process, e.g., polishing a substrate with a polishing pad, have a large variety of applications, for example, for polishing of glass, ceramic, or metal materials, and are often designed for use in a chemical mechanical planarization (CMP) process. In a typical CMP process, the relative movement of the slurry to a substrate to be polished assists with the planarization (polishing) process by chemically and mechanically interacting with the exterior surface of the substrate and removing unwanted material. Polishing is conducted until a desired smooth exterior surface with a low surface roughness is obtained. There exists a need of developing cost efficient polishing compositions which can contribute to a high material removal rate during polishing and lead to polished substrates having a low surface roughness.

### DETAILED DESCRIPTION

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

The present disclosure is directed to a polishing composition adapted for conducting a material removing operation. The composition can comprise a permanganate salt in an amount of at least 2.5 wt %, an aluminum (III) salt in an amount of at least 0.2 wt %, and water, wherein the pH of the polishing composition may be not greater than 4.5. It has been surprisingly observed that the polishing composition of the present disclosure can conduct polishing of a substrate including silicon carbide with at a high material removal rate and a desired low surface roughness.

In one particular embodiment, the polishing composition of the present disclosure can be essentially free of abrasive particles. As used herein, essentially free of abrasive particles means that an amount of abrasive particles is not greater than 0.1 wt %, or not greater than 0.05 wt %, or not greater than 0.01 wt %. In another aspect, the polishing composition may be free of abrasive particles except for unavoidable impurities.

It has been surprisingly observed that the efficiency of the potassium permanganate salt as oxidizing agent can be greatly enhanced if an aluminum (III) salt is further contained in an abrasive slurry composition. Not to be bound to theory, it is assumed that a synergistic effect is obtained of the aluminum (III) salt with the permanganate ion when chemically altering the surface of a substrate material during polishing.

In one embodiment, the composition of the present disclosure can be made by dissolving the aluminum (III) salts and the permanganate salt in the water, and adjusting the pH of the polishing to the desired pH.

In one aspect, the aluminum (III) salt can be selected from aluminum (III) nitrate or aluminum (III) acetate. In a particular aspect, the aluminum (III) salt can be aluminum (III) nitrate (Al(NO₃)₃).

The amount of the aluminum (III) salt can be at least 0.1 wt % based on the total weight of the polishing composition, or at least 0.2 wt %, or at least 0.3 wt %, or at least 0.5 wt %, or at least 0.07 wt %, or at least 0.8 wt %, or at least 1 wt %, or at least 2 wt %, or at least 3 wt %. In another aspect, the amount of the aluminum (III) salt may be not greater than 20 wt % based on the total weight of the composition, or not greater than 10 wt %, or not greater than 5 wt %, or not greater than 4 wt %, or not greater than 2 wt %, or not greater than 1 wt %. The amount of aluminum (III) salt can be a value between any of the minimum and maximum values noted above, such as at least 0.1 wt % and not greater than 5 wt %, or at least 0.2 wt % and not greater than 2 wt %, or at least 0.25 wt % and not greater than 1.2 wt % based in the total weight of the composition.

In one non-limiting embodiment, the composition may have a molar ratio of total Al³⁺ ions to total MnO₄⁻ ions within a range of 1:5 to 1:50. In one embodiment, the molar ratio of Al³⁺ ions to permanganate ions can be not greater than 1:5, or not greater than 1:8, or not greater than 1:10, or not greater than 1:15, or not greater than 1:20. In another embodiment, the ratio of Al³⁺ ions to permanganate ions may be at least 1:50, or at least 1:40, or at least 1:30, or at least 1:20, or at least 1:15. The molar ratio of the Al³⁺ ions to MnO₄⁻ ions can be a value between any of the minimum and maximum values noted above, such as from 1:5 to 1:50, or from 1:10 to 1:30, or from 1:10 to 1:20.

The amount of the permanganate salt in the polishing composition can be at least 2.5 wt % based on the total weight of the polishing composition, or at least 2.8 wt %, or at least 3.0 wt %, or at least 3.5 wt %, or at least 4.0 wt %, or at least 4.5 wt %, or at least 5.0 wt %, or at least 5.2 wt %, or at least 5.4 wt %, or at least 5.6 wt %, or at least 5.8 wt %, or at least 6.0 wt %, or at least 6.5 wt, or at least 7.0 wt %, or at least 8 wt %, or at least 9 wt %, or at least 10 wt %. In another aspect, the amount of the permanganate salt may be not greater than 15 wt %, or not greater than 12 wt %, or not greater than 10 wt %, or not greater than 8 wt %, or not greater than 6 wt %, or not greater than 5.8 wt %, or not greater than 5.6 wt %. The amount of the permanganate salt can be a value between any of the minimum and maximum values noted above, such as at least 4.5 wt % and not greater than 8 wt %, or at least 5.0 wt % and not greater than 6 wt %, based on the total weight of the polishing composition.

The polishing composition can further comprise one or more optional additives, for example a surfactant, or a dispersant, or a chelating agent, a pH buffer, a rheology modifier, a corrosion resistant agent, one or more further solvents, or any combination thereof.

In a certain embodiment, the polishing composition of the present disclosure can consist essentially of a permanganate salt, an aluminum (III) nitrate salt, and water. Consisting essentially means that an amount of other ingredients or impurities contained in the polishing composition is not greater than 0.1 wt %, or not greater than 0.05 wt %, or not greater than 0.01 wt %, or not greater than 0.005 wt %, or not greater than 0.001 wt % based on the total weight of the polishing composition.

The pH of the polishing composition can be within a range of at least 1.5 and not greater than 4.5. In certain aspects, the pH can be at least 1.8, or at least 2.0, or at least 2.2, or at least 2.5, or at least 2.7, or at least 3.0, or at least 3.2. In other aspects, the pH of the composition may be not greater than 4.5, such as not greater than 4.3, or not greater than 4.1, or not greater than 4.0, or not greater than 3.9, or not greater than 3.8, or not greater than 3.7, or not greater than 3.6, or not greater than 3.5. The pH of the polishing composition can be a value between any of the minimum and maximum values noted above, such as at least 1.5 and not greater than 4.5, at least 2.0 and not greater than 4.2, or at least 2.2 and not greater than 4.0. In a particular aspect, the pH can be at least 3.0 and not greater than 4.5, or at least 3.5 and not greater than 4.5, which has the advantage of working under conditions that are less corrosive.

In a certain aspect, the polishing composition can be free of a corrosion protection agent.

In another certain aspect, a second oxidizing agents can be included in the polishing composition. Non-limiting examples can be, in this regard a peroxide, a peroxodisulfate, a chlorite, a perchlorate, a hypochlorite, an iodate, a periodate, bromine, a nitrite, a hyponitrite, a chromate, or any combination thereof.

In another embodiment, the polishing composition of the present disclosure can comprise abrasive particles. The abrasive particles may not be limited to a specific material type and can include, for example, zirconia, alumina, silica, diamond, cubic boron nitride, ceria, iron oxide, titanium oxide, manganese oxide, lanthanium oxide, or any combination thereof. In a particular aspect, the abrasive particles can be selected from alumina, zirconia, manganese dioxide, ceria, silica, diamond, or iron oxide. In one certain aspect, the abrasive particles can be alumina. In another certain aspect, the abrasive particles can be zirconia.

The average size (D50) of the abrasive particles can be at least 10 nm, or at least 25 nm, or at least 50 nm, at least 80 nm, at least 100 nm, at least 130 nm, or at least 150 nm, at least at least 180 nm, or at least 200 nm, or at least 250 nm. In another embodiment, the average particle size may be not greater than 50 microns, such as not greater than 20 microns, not greater than 10 microns, not greater than 5 microns, not greater than 1 micron, not greater than 0.8 microns, not greater than 0.5 microns, or not greater than 0.3 microns. The average particle size of the abrasive particles can be a value between any of the minimum and maximum values noted above, for example, at least 50 nm and not greater than 500 nm, at least 70 nm and not greater than 250 nm, or at least 80 nm and not greater than 200 nm.

In one embodiment, the amount of the abrasive particles can be at least 0.01 wt % based on a total weight of the composition, or at least 0.05 wt %, or at least 0.1 wt %, or at least 0.5 wt %, or at least 1 wt %, or at least 2 wt %, or at least 3 wt %, or at least 4 wt %, or at least 5 wt %. In another embodiment, the amount of the abrasive particles can be not greater than 50 wt %, such as not greater than 40 wt %, or not greater than 30 wt %, or not greater than 20 wt %, or not greater than 15 wt %, or not greater than 10 wt %, or not greater than 8 wt %, or not greater than 5 wt %. The amount of abrasive particles can be a value between any of the minimum and maximum values noted above. In a particular aspect, the amount of abrasive particles can be at least 0.1 wt % and not greater than 5 wt %.

The present disclosure is further directed to a method of polishing a substrate. The method can comprise: providing the polishing composition of the present disclosure described above, bringing the polishing composition in direct contact with the substrate; and polishing the substrate surface. In one aspect, the substrate can be polished with a polishing pad, wherein the polishing pad and the substrate may move relative to one another and the polishing composition can be in contact with the substrate and the polishing pad.

In one embodiment, the temperature of the polishing composition during polishing can be room temperature (20-25° C.), or at least 30° C., or at least 40° C., or at least 45° C., or at least 50° C., or at least 55° C., or at least 60° C., or at least 65° C. In another embodiment, the temperature of the composition during polishing may be not greater than 90° C., or not greater than 85° C., or not greater than 80° C., or not greater than 75° C., or not greater than 70° C. The temperature of the composition during polishing can be a value in a range between any of the minimum and maximum values noted above.

In another particular aspect, the surface roughness of the substrate after polishing can be not greater than 5 Å, or not greater than 4 Å, or not greater than 3 Å, or not greater than 2.5 Å, or not greater than 2 Å.

In one embodiment the substrate to be polished can include a ceramic material, a metal, a metal alloy, diamond, or a polymer. In a particular embodiment, the substrate can be a group III-V compound, for example, gallium nitride. In another particular embodiment, the substrate can be a group IV-IV compound, for example, silicon carbide. Non-limiting examples of a polymer can be a polyacrylate, a polymethacrylate, a polyimide, a polyolefine, a polyacrylamide, a polyester, a polyurethane, or any combination, such as co-polymers of cross-polymers thereof, as used, e.g., in a photo-resist.

In one aspect, the polishing composition and method of the present disclosure can be adapted for polishing a silicon carbide substrate according to a material removal rate of at least 3.5 μm/hour, or at least 3.7 μm/hour, or at least 3.9 μm/hour, or at least 4 μm/hour, or at least 4.2 μm/hour, or at least 4.4 μm/hour, or at least 4.6 μm/hour, or at least 4.8 μm/hour, or at least 5.0 μm/hour, or at least 5.5 μm/hour, or at least 6.0 μm/hour, or at least 6.5 μm/hour, or at least 7 μm/hour, or at least 7.5 μm/hour, or at least 8 μm/hour, or at least 8.5 μm/hour, or at least 9 μm/hour. As used herein, the method for evaluating the polishing efficiency of polishing a silicon carbide substrate is conducted at room temperature and the following polishing conditions: polishing pad CMC D100; down force 6 psi, platen speed 103 rpm, carrier speed 123 rpm, slurry flow rate 75 ml/mi, polishing machine: Strasbaugh 6EC single sided polishing tool. This test method is described herein also as “silicon carbide polishing test.”

It has been surprisingly discovered that the polishing composition of the present disclosure can assist a chemical mechanical polishing process and may contribute to a high material removal rate when polishing a substrate, together with a smooth exterior surface of the polished substrate with a low surface roughness.

As further demonstrated in the Examples below, it has been surprisingly observed that the polishing composition of the present disclosure, without the addition of abrasive particles, can be suitable for chemical mechanical polishing a substrate with a high material removal rate, especially for silicon carbide containing substrates, and excellent surface finish.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the embodiments as listed below.

### Embodiments

Embodiment 1. A polishing composition comprising: a permanganate salt, an aluminum (III) salt, and water, wherein an amount of the permanganate salt is at least 2.5 wt % based on a total weight of the polishing composition;
an amount of the aluminum (III) salt is at least 0.2 wt % based on the total weight of the polishing composition; and a pH of the composition is not greater than 4.5.

Embodiment 2. A polishing composition comprising: an aluminum (III) salt, at least one permanganate salt in an amount of at least 4.5 wt % based on a total weight of the polishing composition, and water, wherein a pH of the polishing composition is not greater than 4.5; and
the polishing composition is configured to polish a substrate including silicon carbide with an average material removal rate (MMR) of at least 2.5 μm/hour according to a silicon carbide polishing test.

Embodiment 3. The polishing composition of any one of Embodiments 1 or 2, wherein the aluminum (III) salt includes aluminum nitrate, or aluminum acetate, or a combination thereof.

Embodiment 4. The polishing composition of Embodiment 3, wherein the aluminum (III) salt includes aluminum nitrate (Al(NO₃)₃).

Embodiment 5. The polishing composition of Embodiment 4, wherein the aluminum (III) salt consists essentially of aluminum nitrate.

Embodiment 6. The polishing composition of any one of the preceding Embodiments, wherein the composition is essentially free of abrasive particles.

Embodiment 7. The polishing composition of Embodiment 6, wherein the composition is free of abrasive particles.

Embodiment 8. The polishing composition of any one of the preceding Embodiments, wherein the permanganate salt includes potassium permanganate or sodium permanganate.

Embodiment 9. The polishing composition of Embodiment 8, wherein the permanganate salt includes potassium permanganate.

Embodiment 10. The polishing composition of any one of the preceding Embodiments, wherein the amount of the permanganate salt is at least 2.8 wt % based on the total weight of the polishing composition, or at least 3.0 wt %, or at least 3.5 wt %, or at least 4.0 wt %, or at least 4.5 wt %, or at least 5.0 wt %, or at least 5.2 wt %, or at least 5.4 wt %, or at least 5.6 wt %, or at least 5.8 wt %, or at least 6.0 wt %, or at least 6.5 wt, or at least 7.0 wt %, or at least 8 wt %, or at least 9 wt %, or at least 10 wt %.

Embodiment 11. The polishing composition of any one of the preceding Embodiments, wherein the amount of the permanganate salt is not greater than 15 wt %, or not greater than 12 wt %, or not greater than 10 wt %, or not greater than 8 wt %, or not greater than 6 wt %, or not greater than 5.8 wt %, or not greater than 5.6 wt %.

Embodiment 12. The polishing composition of any one of the preceding Embodiments, wherein the amount of the aluminum (III) salt is at least 0.3 wt % based on the total weight of the composition, or at least 0.5 wt %, or at least 0.8 wt %, or at least 1.0 wt %, or at least 1.2 wt %, or at least 1.4 wt %, or at least 1.6 wt %, or at least 1.8 wt %, or at least 2.0 wt %.

Embodiment 13. The polishing composition of any one of the preceding Embodiments, wherein the amount of the aluminum (III) salt is not greater than 5 wt %, or not greater than 4 wt %, or not greater than 3 wt %, or not greater than 2.5 wt %, or not greater than 2.0 wt %, or not greater than 1.5 wt %.

Embodiment 14. The polishing composition of any one of the preceding Embodiments, wherein the pH of the polishing composition is not greater than 4.2, or not greater than 4.0, or not greater than 3.8, or not greater than 3.6.

Embodiment 15. The polishing composition of any one of the preceding Embodiments, wherein the pH of the polishing composition is at least 2.0, or at least 2.2, or at least 2.5, or at least 2.8, or at least 3.0, or at least 3.3, or at least 3.5.

Embodiment 16. The polishing composition of any one of the preceding Embodiments, wherein the pH of the polishing composition is at least 3.0 and not greater than 4.5, or at least 3.5 and not greater than 4.5, or at least 3.5 and not greater than 4.0.

Embodiment 17. The polishing composition of any one of the preceding Embodiments, wherein the polishing composition further comprises abrasive particles.

Embodiment 18. The polishing composition of Embodiment 17, wherein the abrasive particles include alumina, silica, ceria, or zirconia.

Embodiment 19. The polishing composition of any one of Embodiments 17 or 18, wherein an amount of the abrasive particles is at least 0.05 wt % based on the total weight of the composition, or at least 0.1 wt %, or at least 0.5 wt %, or at least 1.0 wt %, or at least 2.0 wt %.

Embodiment 20. The polishing composition of any one of Embodiments 17 to 19, wherein an amount of the abrasive particles is not greater than 10 wt % based on the total weight of the composition, or not greater than 8 wt %, or not greater than 5 wt %, or not greater than 3 wt %, or not greater than 2 wt %, or not greater than 1 wt %, or not greater than 0.5 wt %.

Embodiment 21. The polishing composition of any one of the preceding Embodiments, wherein the composition further comprises a surfactant, or a dispersant, or a chelating agent, or a pH buffer, or a rheology modifier, or a corrosion resistant agent, or any combination thereof.

Embodiment 22. The polishing composition of any one of Embodiments 2 to 21, wherein the composition is designed for polishing the substrate including silicon carbide with the material removal rate of at least 3.7 μm/hour, or at least 3.9 μm/hour, or at least 4.0 μm/hour, or at least 4.2 μm/hour, or at least 4.4 μm/hour, or at least 4.6 μm/hour, or at least 4.8 μm/hour, or at least 5.0 μm/hour.

Embodiment 23. A method of polishing a substrate, comprising: providing a substrate and a polishing composition; and polishing the substrate with the composition using a polishing pad, wherein the composition comprises a permanganate salt, an aluminum (III) nitrate salt, and water, wherein an amount of the permanganate salt is at least 2.5 wt %; an amount of the aluminum (III) nitrate salt is at least 0.2 wt %; and a pH of the composition is at least 3.0 and not greater than 4.5.

Embodiment 24. The method of Embodiment 23, wherein the composition is essentially free of abrasive particles.

Embodiment 25. The method of Embodiment 24, wherein the composition is free of abrasive particles.

Embodiment 26. The method of any one of Embodiments 25 to 25, wherein the substrate includes a ceramic material, a metal, a metal alloy, diamond, a polymer, a group III-V compound, or a group IV-IV compound.

Embodiment 27. The method of Embodiment 26, wherein the substrates includes silicon carbide.

Embodiment 28. The method of any one of Embodiments 23 to 27, wherein the aluminum (III) salt includes aluminum nitrate.

Embodiment 29. The method of any one of Embodiments 23 to 28, wherein the permanganate salt includes potassium permanganate or sodium permanganate.

Embodiment 30. The method of Embodiment 29, wherein the permanganate salt includes potassium permanganate.

Embodiment 31. The method of any one of Embodiments 23 to 30, wherein the amount of the permanganate salt is at least 2.8 wt % based on the total weight of the composition, or at least 3.0 wt %, or at least 3.5 wt %, or at least 4.0 wt %, or at least 4.5 wt %, or at least 5.0 wt %, or at least 5.2 wt %, or at least 5.4 wt %, or at least 5.6 wt %, or at least 5.8 wt %, or at least 6.0 wt %, or at least 6.5 wt, or at least 7.0 wt %, or at least 8 wt %, or at least 9 wt %, or at least 10 wt %.

Embodiment 32. The method of any one of Embodiments 23 to 31, wherein the amount of the permanganate salt is not greater than 15 wt %, or not greater than 12 wt %, or not greater than 10 wt %, or not greater than 8 wt %, or not greater than 6 wt %, or not greater than 5.8 wt %, or not greater than 5.6 wt %.

Embodiment 33. The method of any one of Embodiments 23 to 32, wherein the amount of the aluminum (III) salt is at least 0.8 wt % based on the total weight of the composition, or at least 1.0 wt %, or at least 1.2 wt %, or at least 1.4 wt %, or at least 1.6 wt %, or at least 1.8 wt %, or at least 2.0 wt %.

Embodiment 34. The method of any one of Embodiments 23 to 33, wherein the amount of the aluminum (III) salt is not greater than 5 wt %, or not greater than 4 wt %, or not greater than 3 wt %, or not greater than 2.5 wt %, or not greater than 2.0 wt %, or not greater than 1.5 wt %.

Embodiment 35. The method of any one of Embodiments 23 to 34, wherein the pH of the composition is not greater than 4.2, or not greater than 4.0, or not greater than 3.8, or not greater than 3.6, or not greater than 3.6.

Embodiment 36. The method of any one of Embodiments 23 to 36, wherein the pH of the composition is at least 2.0, or at least 2.2, or at least 2.5, or at least 2.8, or at least 3.0, or at least 3.5.

Embodiment 37. The method of any one of Embodiments 23 to 36, wherein the method is designed to polish a substrate including silicon carbide with a material removal rate (MMR) of at least 3.5 μm/hour, or at least 4.0 μm/hour, or at least 4.5 μm/hour, or at least 5.0 μm/hour, or at least 5.5 μm/hour, or at least 6.0 μm/hour, or at least 6.5 μm/hour, or at least 7.0 μm/hour, or at least 7.5 μm/hour, or at least 8.0 μm/hour, or at least 8.5 μm/hour, or at least 9.0 μm/hour.

Embodiment 38. The method of any one of Embodiments 23 to 37, wherein the composition further comprises abrasive particles.

Embodiment 39. The method of Embodiment 38, wherein the abrasive particles include alumina, silica, ceria, or zirconia.

Embodiment 40. The method of any one of Embodiments 38 or 39, wherein an amount of the abrasive particles is at least 0.05 wt % based on the total weight of the composition, or at least 0.1 wt %, or at least 0.5 wt %, or at least 1.0 wt %, or at least 2.0 wt %.

Embodiment 41. The method of any one of Embodiments 38 to 40, wherein an amount of the abrasive particles is not greater than 10 wt % based on the total weight of the composition, or not greater than 8 wt %, or not greater than 5 wt %, or not greater than 3 wt %, or not greater than 2 wt %, or not greater than 1 wt %, or not greater than 0.5 wt %.

Embodiment 42. The method of any one of Embodiments 23 to 41, wherein the composition further comprises a surfactant, or a dispersant, or a chelating agent, or a pH buffer, or a rheology modifier, or a corrosion resistant agent, or any combination thereof.

### Examples

The following non-limiting examples illustrate the present invention.

### Example 1

Aqueous polishing compositions were prepared by dissolving potassium permanganate (KMnO4) and aluminum nitrate nonahydrate in water.

Each polishing composition was evaluated according to its polishing efficiency by measuring the material removal rate (MMR) when polishing a silicon carbide test wafer.

As silicon carbide test wafers were used 4H-type silicon carbide (4° off-axis) wafers having a diameter of 150 mm.

The silicon carbide (SiC) wafer polishing was conducted according to the method describe below. The material removal rate (MMR) was calculated from the weight loss of the SiC wafers measured with an Ohaus Explorer Model FX324 precision scale.

Polishing method: polishing pad CMC D100; down force 6 psi, platen speed 103 rpm, carrier speed 123 rpm, slurry flow rate 75 ml/mi, polishing machine: Strasbaugh 6EC single sided polishing tool, at room temperature.

In a set of preliminary experiments it was observed that at potassium permanganate (KMnO₄) concentrations of 2.5 wt % and larger in the presence of Al³⁺ ions an enhanced increase in the silicon dioxide material removal rate (MRR) could be obtained, wherein the best results were obtained at KMnO₄ concentrations between 4 and 6 wt %. The following experiments center on investigations of the amount of Al³⁺ ions (added in form of aluminum nitrate nonahydrate and the pH on the polishing efficiency (MMR).

A first series of samples was prepared by varying the amount of the aluminum nitrate salt, wherein the amount of aluminum nitrate nonahydrate was increased from 0% up to 3 wt %, and the amount of KMnO₄ was for each sample 4 wt % (see samples S1-S4 and comparative sample C1). A summary of the polishing compositions and the obtained SiC material removal rate (MRR) is shown in Table 1. As used herein, the term “aluminum nitrate nonahydrate” is also expressed also as Al(NO₃)₃ or aluminum nitrate, but the recited weight % amounts refer to aluminum nitrate nonahydrate.

TABLE 1

| | Amount of KMnO₄ | Amount of | | |
|---|---|---|---|---|
| Sample | [wt %] | Al(NO₃)₃ [wt %] | pH | MRR [μm/h] |
| C1 | 4.0 | 0 | 2.0 | 3.29 |
| S1 | 4.0 | 0.25 | 2.0 | 3.76 |
| S2 | 4.0 | 0.5 | 2.0 | 3.68 |
| S3 | 4.0 | 1.0 | 2.0 | 4.21 |
| S4 | 4.0 | 3.0 | 2.0 | 3.09 |

It can be seen from the data summarized in Table 1 that the highest MRR was achieved with an Al(NO₃)₃ concentration of 1 wt %.

A second series of samples was designed to investigate the influence of the Al(NO₃)₃ amount in the range between 1 wt % and 2 wt %, while the amount of KMnO₄ was 6 wt % and the selected pH was 4.5 (see Table 2). The data show that also in this series the highest MRR was obtained with 1 wt % Al(NO₃)₃, while the MRR decreased at higher Al³⁺ concentrations.

TABLE 2

| | Amount of KMnO₄ | Amount of | | |
|---|---|---|---|---|
| Sample | [wt %] | Al(NO₃)₃ [wt %] | pH | MRR [μm/h] |
| S5 | 6.0 | 1.0 | 4.5 | 3.96 |
| S6 | 6.0 | 1.5 | 4.5 | 3.91 |
| S7 | 6.0 | 2.0 | 4.5 | 3.81 |

In a third series of samples (compositions S8-S11), the pH was varied between pH 2.1 and 5.5, while the amount of KMnO4 was 6.0 wt % and the amount of Al(NO₃)₃ was 1 wt %. A summary of the polishing results is shown in Table 3.

TABLE 3

| | Amount of KMnO₄ | Amount of | | |
|---|---|---|---|---|
| Sample | [wt %] | Al(NO₃)₃ [wt %] | pH | MRR [μm/h] |
| S8 | 6.0 | 1 | 2.1 | 3.82 |
| S9 | 6.0 | 1 | 3.5 | 4.19 |
| S10 | 6.0 | 1 | 4.5 | 4.65 |
| S11 | 6.0 | 1 | 5.5 | 0.60 |

The data in Table 3 show that the highest MRR was achieved at a pH in the range of 3.5 to 4.5, and a strong decline in the MRR was observed at pH 5.5. It was a surprising observation that the highest polishing efficiency was obtained in the pH range of 3.5 to 4.5. This can have the advantage that polishing under highly acid conditions can be avoided, which is typically in the field of SiC polishing at pH2 or lower. By increasing the pH value to the range, for example, from pH 3.0 to pH 4.5, the susceptibility to corrosion can be reduced.

Table 4 shows data wherein the MRR of polishing compositions was compared containing 5.5 wt % KMnO₄, 1 wt % aluminum nitrate nonahydrate, and the pH was varied between 3.5 and 11. The results are conform with the results contained in Table 3, showing that at high pH values the MRR drastically declined. At a pH 11, nearly no polishing effect could be achieved.

TABLE 4

| | Amount of KMnO₄ | Amount of | | |
|---|---|---|---|---|
| Sample | [wt %] | Al(NO₃)₃ [wt %] | pH | MRR [μm/h] |
| S12 | 5.5 | 1 | 3.5 | 4.91 |
| S13 | 5.5 | 1 | 9.0 | 0.76 |
| S14 | 5.5 | 1 | 10.0 | 0.18 |
| S15 | 5.5 | 1 | 11.0 | 0.44 |

### Example 2

A series of polishing compositions was prepared with the aim of comparing the MRR when using different permanganate salts in combination with aluminum nitrate salt, such as potassium permanganate (KMnO₄) and sodium permanganate (NaMnO₄).

A summary of the tested polishing compositions and the obtained material removal rates (MMR) is shown in Table 5. It can be seen that both, KMnO₄ and NaMnO₄, had a high MMR for polishing the SiC wafers, wherein the polishing rate was about 30% higher if KMnO₄ was used in comparison to the composition including NaMnO₄.

TABLE 5

| | | Amount of | | |
|---|---|---|---|---|
| Sample | Permanganate-Salt | Al(NO₃)₃ [wt %] | pH | MRR [μm/h] |
| S12 | 6.0 wt % KMnO₄ | 1 | 3.5 | 4.43 |
| S13 | 6.0 wt % NaMnO₄ | 1 | 3.5 | 4.07 |
| S14 | 12 wt % NaMnO4 | 1 | 3.5 | 3.55 |
| S15 | 6 wt % KMnO4 and | 1 | 3.5 | 4.02 |
| | 6 wt % KMnO4 | | | |

Furthermore, comparative compositions were made and tested by replacing potassium permanganate with a variety of other oxidizing agents, such as hydrogen peroxide, oxone, ammonium persulfate, and potassium persulfate. A summary of the polishing compositions and polishing test results is shown in Table 6. It can be seen that the polishing compositions wherein the permanganate salt was replaced with hydrogen peroxide, oxone, ammonium persulfate, and potassium persulfate were not suitable for silicon carbide polishing. The material removing rate of silicon carbide when using the comparative polishing compositions C2-C5 was zero.

TABLE 6

| | | Amount of | | |
|---|---|---|---|---|
| Sample | Oxidizing Agent | Al(NO₃)₃ [wt % ] | pH | MMR [μm/h] |
| C2 | 5.5 wt % H₂O₂ | 1 | 3.5 | 0 |
| C3 | 5.5 wt % Oxone | 1 | 3.5 | 0 |
| C4 | 5.5 wt % | 1 | 3.5 | 0 |
| | (NH₄)₂S₂O₈ | | | |
| C5 | 4.5 wt % K₂S₂O₈ | 1 | 3.5 | 0 |

### Example 3

Polishing compositions were prepared with the aim to compare different Al³⁺ salts with regard to their influence on the MRR: aluminum nitrate nonahydrate, aluminum acetate, and aluminum sulfate. In each composition, the amount of the Al³⁺ salt was 1 wt %, the amount of KMnO₄ was 5.5 wt %, and the pH was 3.5. It could be observed that the polishing composition containing aluminum nitrate had the highest MRR for silicon carbide. If aluminum nitrate was replaced by aluminum acetate the MRR for silicon carbide was about 20 percent lower. By replacing aluminum nitride with aluminum sulfate the composition had nearly no capability of the polishing the SiC wafer.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of the invention.

What is claimed is:

1. A polishing composition comprising: an aluminum (III) salt, a permanganate salt, and water, wherein
an amount of the permanganate salt is at least 2.5 wt % based on a total weight of the polishing composition;
an amount of the aluminum (III) salt is at least 0.2 wt % based on the total weight of the polishing composition; and
a pH of the polishing composition is not greater than 4.5.

2. A polishing composition comprising: an aluminum salt, at least one permanganate salt in an amount of at least 2.5 wt % based on a total weight of the polishing composition, and water, wherein
a pH of the polishing composition is not greater than 4.5; and
the polishing composition is configured to polish a substrate including silicon carbide with an average material removal rate (MMR) of at least 3.5 μm/hour according to a test silicon carbide polishing test.

3. The polishing composition of claim 1, wherein the aluminum (III) salt includes aluminum nitrate, or aluminum acetate.

4. The polishing composition of claim 3, wherein the aluminum (III) salt consists essentially of aluminum nitrate.

5. The polishing composition of claim 1, wherein the composition is essentially free of abrasive particles.

6. The polishing composition of claim 1, wherein the permanganate salt includes potassium permanganate or sodium permanganate.

7. The polishing composition of claim 6, wherein the permanganate salt includes potassium permanganate.

8. The polishing composition of claim 1, wherein the amount of the permanganate salt is at least 4 wt % based on the total weight of the polishing composition.

9. The polishing composition of claim 1, wherein the amount of the aluminum (III) salt is at least 0.5 wt % based on the total weight of the composition.

10. The polishing composition of claim 1, wherein the pH of the polishing composition is at least 3.0 and not greater than 4.5.

11. The polishing composition of claim 1, wherein the amount of aluminum (III) salt is at least 0.50 wt % based on the total weight of the polishing composition, the amount of permanganate salt is at least 4 wt % based on the total weight of the polishing composition, and the pH of the polishing composition is at least 3.0 and not greater than 4.5.

12. The polishing composition of claim 1, wherein the polishing composition further comprises abrasive particles.

13. The polishing composition of claim 12, wherein the abrasive particles include alumina, silica, ceria, or zirconia.

14. The polishing composition of claim 12, wherein an amount of the abrasive particles is at least 0.05 wt % based on the total weight of the polishing composition.

15. The polishing composition of claim 1, wherein the polishing composition further comprises a surfactant, or a dispersant, or a chelating agent, or a pH buffer, or a rheology modifier, or a corrosion resistant agent, or any combination thereof.

16. The polishing composition of claim 1, wherein the polishing composition consists essentially of potassium permanganate, aluminum (III) nitrate and water.

17. A method of polishing a substrate, comprising:
providing a substrate and a polishing composition; and
polishing the substrate with the polishing composition using a polishing pad, wherein the polishing composition comprises an aluminum (III) salt, a permanganate salt, and water, wherein an amount of the permanganate salt is at least 2.5 wt %; an amount of the aluminum (III) salt is at least 0.2 wt %; and a pH of the composition is not greater than 4.5.

18. The method of claim 17, wherein the polishing composition is essentially free of abrasive particles.

19. The method of claim 17, wherein the substrate includes a ceramic material, a metal, a metal alloy, diamond, a polymer, a group III-V compound, or a group IV-IV compound.

20. The method of claim 19, wherein the substrates includes silicon carbide.
